(19) United States
(12) Patent Application Publication
(10) Pub. No.: US 2014/0352428 A1
(43) Pub. Date: Dec. 4, 2014

(54) LIQUID PROPERTY DETECTING DEVICE

(71) Applicant: AISAN KOGYO KABUSHIKI KAISHA, Obu-shi (JP)

(72) Inventor: Nobuhiro Kato, Obu-shi (JP)

(73) Assignee: AISAN KOGYO KABUSHIKI KAISHA, Obu-shi (JP)

(21) Appl. No.: 14/288,650

(22) Filed: May 28, 2014

(30) Foreign Application Priority Data
May 28, 2013 (JP) 2013-111710

(51) Int. Cl. G01F 23/26; G01R 27/26

(52) U.S. Cl. CPC G01F 23/26; G01R 27/2605
USPC 73/304 C

(57) ABSTRACT

A liquid property detecting device may be configured to be disposed in a liquid feeding unit including a container, a pump, and a feed pipe. The liquid property detecting device may comprise a first pair of electrodes and a filter. The first pair of electrodes may be configured to be disposed upstream of the feed pipe in a direction in which the liquid stored in the container flows while the pump is driving. The first pair of electrodes may be configured to detect a liquid property of the liquid stored in the container. The filter may be configured to be disposed upstream of the first pair of electrodes in the direction in which the liquid stored in the container flows while the pump is driving.

### CROSS-REFERENCE TO RELATED APPLICATION

This application claims priority to Japanese Patent Application No. 2013-111710 filed on May 28, 2013, the contents of which are hereby incorporated by reference into the present application.

### TECHNICAL FIELD

The present application discloses a liquid property detecting device configured to be located in a liquid supplying unit.

### DESCRIPTION OF RELATED ART

Japanese Patent Application Publication No. H2-87022 discloses a liquid surface measuring device that measures a liquid surface of fuel. The liquid surface measuring device measures the liquid surface of the fuel stored in a fuel tank by using a capacitance of a pair of electrodes extending in a direction intersecting the liquid surface of the fuel.

### SUMMARY

In a fuel tank, there may be a foreign matter other than fuel. If the foreign matter in the fuel tank makes contact with a pair of electrodes, a capacitance of the pair of electrodes will vary due to the foreign matter. As a result, a liquid surface of the fuel stored in the fuel tank may not be appropriately measured even by using the capacitance of the pair of electrodes. This specification discloses a technology for restraining a foreign matter from malting contact with a pair of electrodes.

The present application discloses that a liquid properly detecting device. The liquid property detecting device may be configured to be disposed in a liquid feeding unit including a container, a pump, and a feed pipe. The pump may suck a liquid stored in the container and send out the liquid toward a liquid-utilizing machine. The pump may have an outlet. The feed pipe may be disposed in the container. The feed pipe may connect the outlet and a discharge opening through which the liquid is discharged out of the container. The liquid property detecting device may comprise a first pair of electrodes and a filter. The first pair of electrodes may be configured to be disposed upstream of the feed pipe in a direction in which the liquid stored in the container flows while the pump is driving. The first pair of electrodes may be configured to detect a liquid property of the liquid stored in the container. The filter may be configured to be disposed upstream of the first pair of electrodes in the direction in which the liquid stored in the container flows while the pump is driving.

In the foregoing liquid property detecting device, while the pump is driving, the liquid filtered by the filter exists around the first pair of electrodes. This configuration causes foreign matters in the liquid to be caught by the filter, thus may restrain the foreign matter from making contact with the first pair of electrodes. As a result, a value obtained by using the first pair of electrodes may be restrained from varying due to the foreign matter. By using the first pair of electrodes, the liquid property of the liquid may be properly measured.

### BRIEF DESCRIPTION OF THE DRAWINGS

FIG. 1 shows a configuration of a fuel tank of a first embodiment and a peripheral area thereof;

FIG. 2 shows a configuration of a liquid property detecting section of the first embodiment;

FIG. 3 shows a configuration of an electrode part of a liquid level detecting section of the first embodiment;

FIG. 4 shows a configuration of a liquid property detecting section of the second embodiment;

FIG. 5 shows a sectional view taken along cross-section V-V of FIG. 4; and

FIG. 6 shows a configuration of a fuel tank of a third embodiment and a peripheral area thereof.

### DETAILED DESCRIPTION

Some features of embodiments described herein will be listed. Notably, technical features described herein are each independent technical element, and exhibit technical usefulness thereof solely or in combinations.

### Feature 1

In the liquid property detecting device, the filter may include a housing space in which the first pair of electrodes is housed. The housing space may be configured to communicate with a suction opening of the pump.

According to this configuration, a filter for restraining a foreign matter from making contact with the first pair of electrodes and a filter for restraining a foreign matter from entering the pump may not be separately provided.

### Feature 2

The liquid property detecting device may comprise a case housing the filter and the first pair of electrodes. The case may be disposed in the container and configured to connect the outlet of the pump and the feed pipe.

According to this configuration, a filter for restraining a foreign matter from making contact with the first pair of electrodes and a filter for restraining a foreign matter from entering the liquid-utilizing machine may not be separately provided.

### Feature 3

The liquid property detecting device may comprise a substrate having a surface on which the first pair of electrodes is disposed. The surface of the substrate may be configured to be disposed in an orientation that faces a bottom surface of the container.

In this configuration, the first pair of electrodes is kept immersed in the liquid until the liquid level of the liquid stored in the container becomes lower than the surface of the substrate. According to this configuration, in a case where the liquid level of the liquid stored in the container lowers, restrain the first pair of electrodes from being exposed above the surface of the liquid may be restrained, as compared with a configuration in which the surface of the substrate is disposed in such an orientation as to face a surface other than the bottom surface of the container. As a result, the capacitance of the first pair of electrodes may be restrained from changing depending on the liquid level of the liquid.

### Feature 4

In the liquid property detecting device, the first pair of electrodes may comprise an outer electrode having a cylindrical shape and an inner electrode being disposed on an inner side of the outer electrode. The inner electrode may face an inner circumferential surface of the outer electrode. The outer electrode may comprise a communicating hole that connects an outer side of the outer electrode and the inner side of the outer electrode.

According to this configuration, the liquid may easily pass through the space between the inner electrode and the outer electrode. As a result, the liquid between the inner electrode and the outer electrode may be prevented from being stagnant.

### Feature 5

The liquid property detecting device may comprise a protective wall covering the first pair of electrodes. The protective wall may be located closer to the first pair of electrodes than the filter member. The protective wall may have liquid permeability.

According to this configuration, the filter may be prevented from making contact with the first pair of electrodes.

### Feature 6

In the liquid property detecting device, the protective wall may be made of a metal material, and grounded.

In this configuration, the case serves as an electromagnetic shield for the first pair of electrodes. According to this configuration, the capacitance of the first pair of electrodes may be restrained from varying depending on an environment surrounding the first pair of electrodes.

### Feature 7

The liquid property detecting device may comprise a second pair of electrodes configured to be disposed in of the container and detect a liquid level of the liquid stored in the container.

According to this configuration, the liquid level of the liquid may be detected by utilizing the liquid property detecting device.

### Feature 8

The liquid property detecting device may comprise a control unit configured to detect the liquid level of the liquid stored in the container by using a capacitance of the first pair of electrodes and a capacitance of the second pair of electrodes.

The capacitance of the second pair of electrodes varies depending on a dielectric constant of the liquid stored in the container. By installing the first pair of electrodes so that the capacitance of the first pair of electrodes does not vary depending on the liquid level of the liquid, the effect of the dielectric constant of the liquid on the capacitance of the second pair of electrodes can be diminished by using the capacitance of the first pair of electrodes. This makes it possible to more accurately detect the liquid level of the liquid.

Feature 9

The liquid property detecting device may comprise a third pair of electrodes configured to be disposed in the container so as to detect the liquid property of the liquid stored in the container and a control unit configured to detect the liquid level of the liquid stored in the container that, using a capacitance of the third pair of electrodes and a capacitance of the second pair of electrodes. The control unit may be configured to output a result of a comparison between the capacitance of the first pair of electrodes and the capacitance of the third pair of electrodes.

In this configuration, by installing the first pair of electrodes so that the capacitance of the third pair of electrodes does not vary depending on the liquid level of the liquid, the effect of the dielectric constant of the liquid on the capacitance of the second pair of electrodes can be diminished by using the capacitance of the third pair of electrodes. This makes it possible to more accurately detect the liquid level of the liquid. Further, the comparison between the capacitance of the first pair of electrodes and the capacitance of the third pair of electrodes makes it possible to notice whether an abnormality has occurred in the first pair of electrodes or in the third pair of electrodes.

Representative, non-limiting examples of the present invention will now be described in further detail with reference to the attached drawings. This detailed description is merely intended to teach a person of skill in the art further details for practicing preferred aspects of the present teachings and is not intended to limit the scope of the invention. Furthermore, each of the additional features and teachings disclosed below may be utilized separately or in conjunction with other features and teachings to provide improved liquid property detecting device, as well as methods for using and manufacturing the same.

Moreover, combinations of features and steps disclosed in the following detailed description may not be necessary to practice the invention in the broadest sense, and are instead taught merely to particularly describe representative examples of the invention. Furthermore, various features of the above-described and below-described representative examples, as well as the various independent and dependent claims, may be combined in ways that are not specifically and explicitly enumerated in order to provide additional useful embodiments of the present teachings.

All features disclosed in the description and/or the claims are intended to be disclosed separately and independently from each other for the purpose of original written disclosure, as well as for the purpose of restricting the claimed subject matter, independent of the compositions of the features in the embodiments and/or the claims. In addition, all value ranges or indications of groups of entities are intended to disclose every possible intermediate value or intermediate entity for the purpose of original written disclosure, as well as for the purpose of restricting the claimed subject matter.

### First Embodiment

A fuel feeding unit 1 of the present embodiment is mounted in an automobile, and feeds fuel to an engine (not illustrated). The fuel-feeing unit 1 includes a fuel tank 10, a fuel pump unit 30, and a sensor device 2. The fuel tank 10 retains mixed fuel of gasoline and ethanol. Into the fuel tank 10, the fuel is fed through a opening (not illustrated).

The fuel pump unit 30 includes a pump body 34, a high-pressure filter 36, a reserve cup 20, a pressure regulator 42, and a discharge port 12. The pump body 34, the high-pressure filter 36, the reserve cup 20, and the pressure regulator 42 are disposed inside of the fuel tank 10. The pump body 34 sucks the fuel stored in the fuel tank 10 through a suction opening 34a of the pump body 34 and pressurizes the fuel inside of the pump body 34. Then, the pump body 34 forces the pressurized fuel into a case 36a of the high-pressure filter 36 through an outlet 34b of the pump body 34.

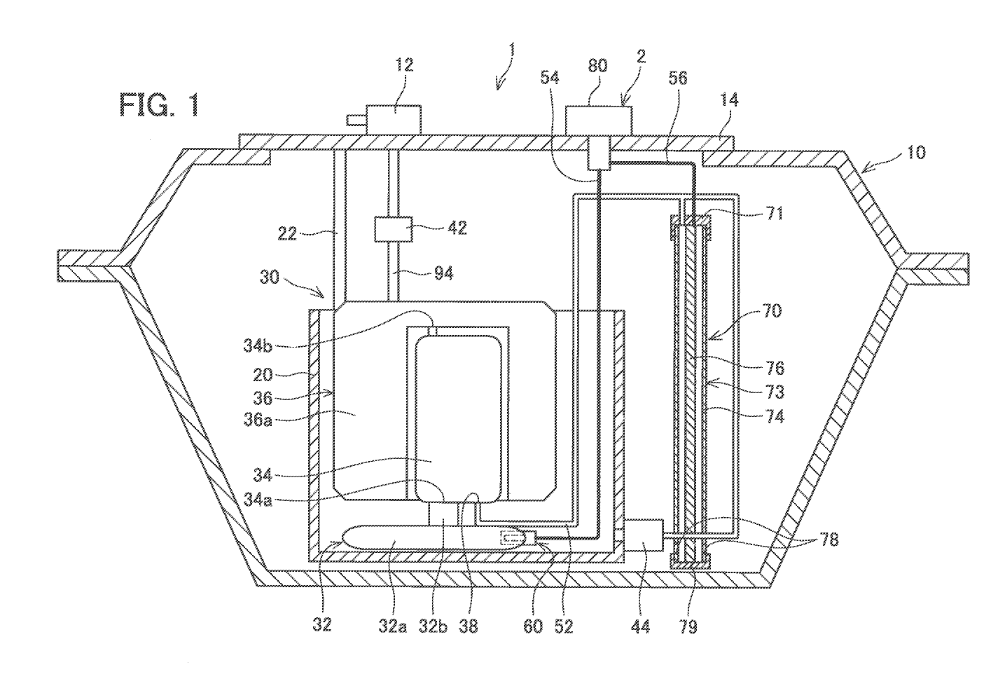

The high-pressure filter 36 includes the case 36a and a filter member (not illustrated). Although illustrated in a simplified manner in FIG. 1, the case 36a is disposed in such a manner as to extend circumferentially around the pump body 34. The fuel having flowed into the case 36a is filtered by the filter member of the high-pressure filter 36, and is sent out into a pipe 94. That is, the filter member is structured to allow the fuel to pass therethrough but make it hard for a foreign matter contained in the fuel to pass therethrough. The pressure regulator 42 is connected to the pipe 94. The pressure regulator 42 releases an excess of the fuel inside of the pipe 94 into the fuel tank 10 when the pressure of the fuel inside of the pressure regulator 42 becomes equal to or higher than a predetermined pressure, thereby adjusting the pressure of the fuel inside of the pipe 94 so that it is a constant pressure. The fuel stored in the fuel tank 10 has its pressure so adjusted by the pump body 34 and the pressure regulator 42 as to be a constant pressure, and is pumped through the discharge port 12 into the engine (not illustrated). The case 36a connects the outlet 34b of the pump body 34 and the pipe 94. The pipe 94 connects the outlet 34b of the pump body 34 and the discharge port 12.

The pump body 34 includes a vapor jet 38. The vapor jet 38 connects a fuel channel inside of the pump body 34 and the fuel tank 10 located lateral to the pump body 34. The vapor jet 38 is a communicating path through which bubbles in the fuel stored in the pump body 34 are forced out of the pump body 34. The fuel pressurized by the pump body 34 is released through the vapor jet 38 into a release pipe 52.

The pump body 34 and the high-pressure filter 36 are disposed inside of the reserve cup 20. The reserve cup 20 is fixed to a set plate 14 of the fuel tank 10 by a prop 22. A jet pump 41 is disposed in a bottom part of the reserve cup 20. The jet pump 44 sends the fuel outside of the reserve cup 20 into the reserve cup 20 by utilizing the velocity of flow of the fuel pumped from the pump body 34 and released through the vapor jet 38. For example, a venturi structure is provided, and while the fuel released through the vapor jet 38 is passing through the venturi, the fuel outside of the reserve cup 20 is sucked into the jet pump 44, so that the fuel sucked from the outside of the reserve cup 20 is sent into the reserve cup 20 together with the fuel released through the vapor jet 38. By providing the reserve cup 20 and the jet pump 44, the liquid level of the fuel in an area around the pump body 34 can be kept high even in a case where the amount of fuel remaining in the fuel tank 10 is small. It should be noted that in a modification, the jet pump 44 may utilize the velocity of flow of the fuel released from the pressure regulator 42 or of the fuel inside of a pipe branching off from the pipe 94.

The sensor device 2 includes a control device 80, a liquid property detecting unit 60, a liquid level detecting unit 70, the release pipe 52, and a low-pressure filter 32. The low-pressure filter 32 includes a filter body 32a and a coupling part 32b. The filter body 32a is made of unwoven fabric in the form of a bag. The filter body 32a houses a frame (not illustrated) that prevents the filter body 32a from being greatly deformed by the pressure of the fuel. The coupling part 32b connects the inner part of the filter body 32a and the suction opening 34a of the pump body 34.

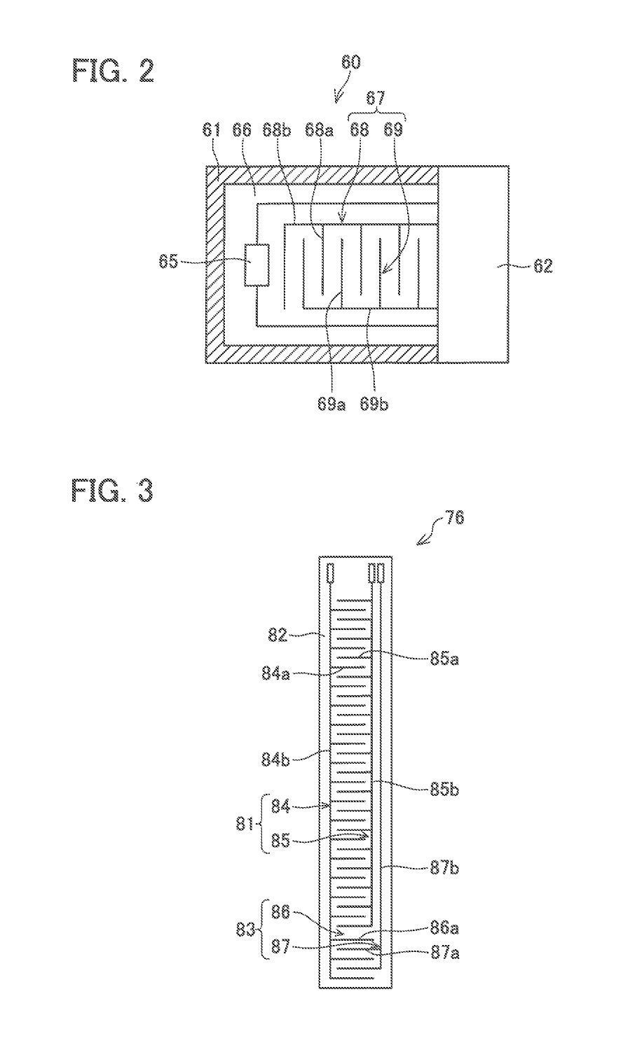

The liquid property detecting unit 60 has a part inserted in the filter body 32a. As shown in FIG. 2, the liquid property detecting unit 60 includes a case 61, a terminal part 62, a substrate 66, a temperature detecting element 65, and an electrode pair 67. The liquid property detecting unit 60 is disposed near the bottom part of the reserve cup 20. For this reason, the liquid property detecting unit 60 is normally completely immersed in the fuel. The case 61 is housed in the filter body 32a, and is fixed to the low-pressure filter 32. The case 61 is in the shape of a closed-end cylinder. The case 61 has an outer wall made of a mesh electrically-conducting material (such as metal). It should be noted that the outer wall of the case 61 may be in the shape of a plate having a plurality of through-holes passing through the outer wall. The case 61 is grounded through the terminal part 62. The case 61 houses the substrate 66. It should be noted that FIG. 2 shows a cross-section of the case 61.

The substrate 66 is a rectangular flat plate. The substrate 66 is disposed parallel to a bottom, surface of the reserve cup 20. The substrate 66 has its lower surface disposed facing a bottom surface of the fuel tank 10 and a bottom surface of the reserve cup 20. The electrode pair 67 and the temperature detecting element 65 are disposed on the lower surface of the substrate 66. The electrode pair 67 includes two electrodes 68 and 69. Each of the electrodes 68 and 69 is made of a thin-film electrically-conducting material (such as gold or a copper alloy). The electrodes 68 and 69 are disposed on the substrate 66 in such a manner as to face each other. Each of the electrodes 68 and 69 is in the shape of a comb. The electrode 68 has a plurality of (four in FIG. 2) portions 68a and a portion 68b extending along the longer sides of the substrate 66, with the plurality of portions 68a electrically connected to one another via the portion 68b. The electrode 69 has a plurality of portions 69a and a portion 69b in a similar manner. The plurality of portions 68a and the plurality of portions 69a are alternately disposed along the longer side of the substrate 66.

The temperature detecting element 65 is an element of which resistance varies in a correlated way depending on the temperature of the temperature detecting element 65.

The terminal part 62 is fixed at one end of the longer side of the substrate 66. The terminal part 62 is disposed lateral to the filter body 32a, and closes an open end of the case 61. The terminal part 62 includes a terminal for connecting the case 61, the electrode pair 67, and the temperature detecting element 65 to the control device 80 via a conducting wire 56. The terminal part 62 is connected to the control device 80 via a conducting wire 54. The case 61, the electrode pair 67, and the temperature detecting element 65 are connected to the control device 80 via the terminal part 62 and the conducting wire 54. The release pipe 52 has one end connected to the vapor jet 38 and the other end connected to the liquid level detecting unit 70. The liquid property detecting unit 60 is assembled to the fuel-feeding unit 1 by attaching, to the case 61 fixed to the low-pressure filter 32, the terminal 62 to which the substrate 66 has been fixed. This configuration makes it possible for the filter body 32a to easily house the substrate 66.

The liquid level detecting unit 70 includes an electrode part 76 and a case 73. The electrode part 76 and the case 73 are disposed lateral to the reserve cup 20. The case 73 includes a side wall 74, an upper wall 71, and a lower wall 79. The side wall 74 is in the shape of a cylinder. The side wall 74 has its lower end closed by the lower wall 79. The lower will 79 has its lower surface located near the bottom surface of the fuel tank 10. The side wall 74 has its upper end closed by the upper wall 71. One or more communicating holes 78 that connect an inner side of the side wall 74 and an outer side of the side wall 74 are formed near the lower end of the side wall 74. The case 73 communicates with the release pipe 52. Part of the fuel released through the vapor jet 38 is released into the case 73. The fuel inside of the case 73 flows out of the case 73 through the communicating hole 78. This causes the liquid level of the fuel inside of the case 73 and the liquid level of the fuel stored in the fuel tank 10 to be the same as each other. The case 73 houses the electrode part 76.

As shown in FIG. 3, the electrode part 76 includes a substrate 82 and two electrode pairs 81 and 83. The substrate 82 is a rectangular flat plate. The substrate 82 extends in the direction of the depth of the fuel tank 10. The two electrode pairs 81 and 83 are disposed on one surface of the substrate 82. The electrode pair 81 includes two electrodes 84 and 85. Each of the electrodes 84 and 85 is made of a thin-film electrically-conducting material (such as gold or a copper alloy). The electrodes 84 and 85 are disposed on the substrate 82 in such a manner as to face each other. Each of the electrodes 84 and 85 is in the shape of a comb and extends along the longer side of the substrate 82 (that is, in the direction of the depth of the fuel tank 10). The electrode 84 has a plurality of (seventeen in FIG. 2) portions 84a and a portion 84b extending along the longer sides of the substrate 82, with the plurality of portions 84a electrically connected to one another via the portion 84b. The electrode 85 has a plurality of portions 85a and a portion 85b in a similar manner. The plurality of portions 84a and the plurality of portions 85a are alternately disposed along the longer side of the substrate 82.

The electrode pair 83 is disposed closer to the bottom surface of the fuel tank 10 than the electrode pair 81. The electrode pair 83 includes two electrodes 86 and 87. Each of the electrodes 86 and 87 is made of a thin-film electrically-conducting material (such as gold or a copper alloy). The electrodes 86 and 87 are disposed on the substrate 82 in such a manner as to face each other. Each of the electrodes 86 and 87 is in the shape of a comb. The electrode 86 has a plurality of portions 86a (three in FIG. 3) and a portion 86b, with the plurality of portions 86a electrically connected to one another via the portion 86b. The electrode 87 has a plurality of portions 87a and a portion 87b (two in FIG. 3) extending along the longer side of the substrate 82, with the plurality of portions 87a electrically connected to each other via the portion 87b. The plurality of portions 86a and the plurality of portions 87a are alternately disposed along the longer sides of the substrate 82. When used under the same conditions, the electrode pairs 83 and 67 have the same capacitances.

The control device 80 is connected to a battery (not illustrated). The control device 80 is supplied with electric power from the battery, converts the electric power into a signal (alternating current) of a predetermined frequency (for example, 10 Hz to 3 MHz), and supplies the signal to each of the electrodes 68, 85, and 87. Furthermore, by using the electric power supplied from the battery, the control device 80 supplies a direct-current voltage to the temperature detecting element 65. It should be noted that the control device 80 grounds the electrodes 69, 84, and 86 and the case 61.

The following describes how the fuel-feeding unit 1 operates. The fuel feeding unit 1 starts driving when a driver starts the automobile, for example, by turning on the ignition switch. When the fuel feeding unit 1 starts driving, the pump body 34 starts driving, and the fuel inside of the reserve cup 20 passes through the low-pressure filter 32 and is sucked through the suction opening 34a into the pump body 34. The filter body 32a has a large number of passage holes through which the fuel passes, and as such, is configured to catch foreign matters contained in the fuel. This configuration makes it possible to prevent the foreign matter from entering the pump body 34. The fuel inside of the pump body 34 is pressurized by an impeller provided in the pump body 34. A part of the fuel pressurized by the impeller is released, through the vapor jet 38 into the release pipe 52 together with the bubbles in the fuel. The fuel released through the vapor jet 38 is released through the release pipe 52 into the case 73 of the liquid level detecting unit 70.

Another part of the fuel pressurized by the impeller is forced into the case 36a of the high-pressure filter 36 through the outlet 34b. The fuel inside of the case 36a is filtered by the filter member of the high-pressure filter 36 and is sent out into the pipe 94. As with the filter body 32a, the filter member of the high-pressure filter 36 has a large number of passage holes through which the fuel passes, and as such, is configured to catch foreign matters contained in the fuel. This configuration makes it possible to restrain a foreign matter from entering the engine.

While the pump body 34 is driven, the control device 80 detects the concentration of ethanol contained in the fuel stored in the fuel tank 10 by using the temperature detecting element 65 and the electrode pair 67. Further, the control device 80 measures, by using the electrode pairs 81 and 83, the liquid level of the fuel stored in the fuel tank 10. Furthermore, the control device 80 detects, by using the electrode pairs 67 and 83, whether or not there is an abnormality occurring in the sensor device 2. The control device 80 repeats these operations until the engine of the automobile is stopped.

Specifically, first, the control device 80 supplies a direct-current voltage to the temperature detecting element 65 and detects the temperature of the temperature detecting element 65 from the value of an electric current passing through the temperature detecting element 65. Since the temperature detecting clement 65 is completely immersed in the fuel, the temperature of the temperature detecting element 65 is substantially the same as the temperature of the fuel stored in the fuel tank la The control device 80 stores a mathematical expression that represents a correlation between the resistance of the temperature detecting element 65 and the temperature of the temperature detecting element 65. The control device 80 calculates the resistance of the temperature detecting element 65 from the value of an electric current passing through the temperature detecting element 65 and, by using the resistance of the temperature detecting element 65 and the mathematical expression, detects the temperature of the temperature detecting element 65, i.e. the temperature of the fuel.

Next, the control device 80 supplies an alternating-current voltage to the electrode 68 of the electrode pair 67 and specifies the capacitance of the electrode pair 67. The electrode pair 67 is completely immersed in the fuel. For this reason, the capacitance of the electrode pair 67 varies in a correlated way depending on the dielectric constant of the fuel but does not vary depending on whether the liquid level of the fuel stored in the fuel tank 10 is high or low. The dielectric constant of the fuel changes depending on the ethanol concentration and the temperature. The control device 80 is mounted with a circuit for converting the capacitance of the electrode pair 67 as measured into the dielectric constant of the fuel. Further, the control device 80 stores a database that indicates a relationship among the dielectric constant of the fuel specified by an experiment or an analysis having been conducted in advance, the temperature of the fuel as detected and the concentration of ethanol in the fuel. The control device 80 refers to the database and detects the concentration of ethanol in the fuel from the dielectric constant of the fuel and the temperature of the fuel as detected. The control device 80 outputs the ethanol concentration thus detected to an ECU (Engine Control Unit; not illustrated). The ECU adjusts, in accordance with the concentration of ethanol in the fuel, the amount of fuel that is fed to the engine.

Next, the control device 80 measures the capacitances of the electrode pairs 81 and 83. The liquid level of the fuel inside of the case 73 is the same as the liquid level of the fuel stored in the fuel tank 10 outside of the case 73. Since the fuel and the gas in the fuel tank 10 are different in dielectric constant from each other, the capacitance of the electrode pair 81 varies in a correlated way depending on the liquid level of the fuel inside of the case 73. Furthermore, the capacitance of the electrode pair 81 varies in a correlated way depending on the dielectric constant of the fuel. Meanwhile, the electrode pair 83 is disposed below the electrode part 81, and as such, is usually completely immersed in the fuel. For this reason, the capacitance of the electrode pair 83 varies in a correlated way depending on the dielectric constant of the fuel but does not vary depending on whether the liquid level of the fuel stored in the fuel tank 10 is high or low The control device 80 is mounted with a circuit for converting the capacitances of the electrode pairs 81 and 83 into the liquid level of the fuel. It should be noted that the control device 80 outputs the liquid level of the fuel as specified to a display device of the automobile. This configuration makes it possible to detect the liquid level of the fuel by utilizing the sensor device 2. Further, the effect of the dielectric constant of the fuel on the capacitance of the electrode pair 81 can be diminished by using the capacitance of the electrode pair 83. This makes it possible to more accurately detect the liquid level of the fuel.

The control device 80 makes a comparison between the capacitance of the electrode pair 67 and the capacitance of the electrode pair 83. The capacitance of the electrode pair 67 and the capacitance of the electrode pair 83 both vary in a correlated way depending on the dielectric constant of the fuel but do not vary depending on whether the liquid level of the fuel is high or low. That is, usually, the capacitance of the electrode pair 67 and the capacitance of the electrode pair 83 are substantially equal or approximate to each other. In a case where the difference between the capacitance of the electrode pair 67 and the capacitance of the electrode pair 83 exceeds a predetermined range of numerical values, the control device 80 outputs, to the display device of the automobile, information indicating that there is an abnormality in the sensor device 2. This allows the driver to notice the abnormality in the sensor device 2.

In the sensor device 2, the electrode pair 67 is housed in the filter body 32a. That is, while the pump body 34 is driving, the electrode pair 67 is located downstream of the filter body 32a in the direction of the flow of the fuel. For this reason, in an area around the electrode pair 67, there exists fuel filtered by the filter body 32a. This configuration causes foreign matters in the fuel to be caught by the filter body 32a, thereby restraining the foreign matters from making contact with the electrode pair 67. This makes it possible to restrain the capacitance of the electrode pair 67 from varying due to contact of the foreign matter with the electrode pair 67. This in turn makes it possible to properly measure the concentration of ethanol in the fuel by using the electrode pair 67.

In the fuel stored in the fuel tank 10, there may be an uneven distribution of ethanol concentrations. For example, immediately after supplying fuel to the fuel tank 10, there may be a difference in ethanol concentration between part of the fuel that has just been put into the fuel tank 10 and part of the fuel that remains in the fuel tank 10. In this case, there is an uneven distribution of concentrations of ethanol in the fuel stored in the fuel tank 10. An even ethanol concentration is achieved by stirring the fuel while it is passing through the filter body 32a. This allows the electrode pair 67 to detect the liquid property of evenly stirred fuel.

The electrode pair 67 is disposed on the lower surface of the substrate 66. This configuration allows the electrode pair 67 to be immersed in the fuel until the liquid level of the fuel inside of the reserve cup 20 becomes, if at all, lower than the lower surface of the substrate 66. This configuration makes it possible to restrain the electrode pair 67 from being exposed on the surface of the fuel.

The electrode pair 67 is housed in the case 61. This configuration makes it possible to prevent the electrode pair 67 from making contact with the filter body 32a in a case where the filter body 32a has been deformed by the pressure of the fuel that is sucked into the pump body 34. This makes it possible to restrain the capacitance of the electrode pair 67 from varying depending on a factor other than the dielectric constant of the fuel.

The low pressure filter 32 has a function of restraining the foreign matter from making contact with the electrode pair 67 and a function of restraining the foreign matter from entering the pump body 34. For this reason, other filter for restraining the foreign matter from entering the pipe body 34 does not need to be disposed separately from the low-pressure filter 32.

The case 61, made of metal (that is, a highly electrically-conducting material), is grounded. The case 61 serves as an electromagnetic shield for the electrode pair 67. This configuration makes it possible to restrain the capacitance of the electrode pair 67 from varying depending on an environment surrounding the electrode pair 67.

### Second Embodiment

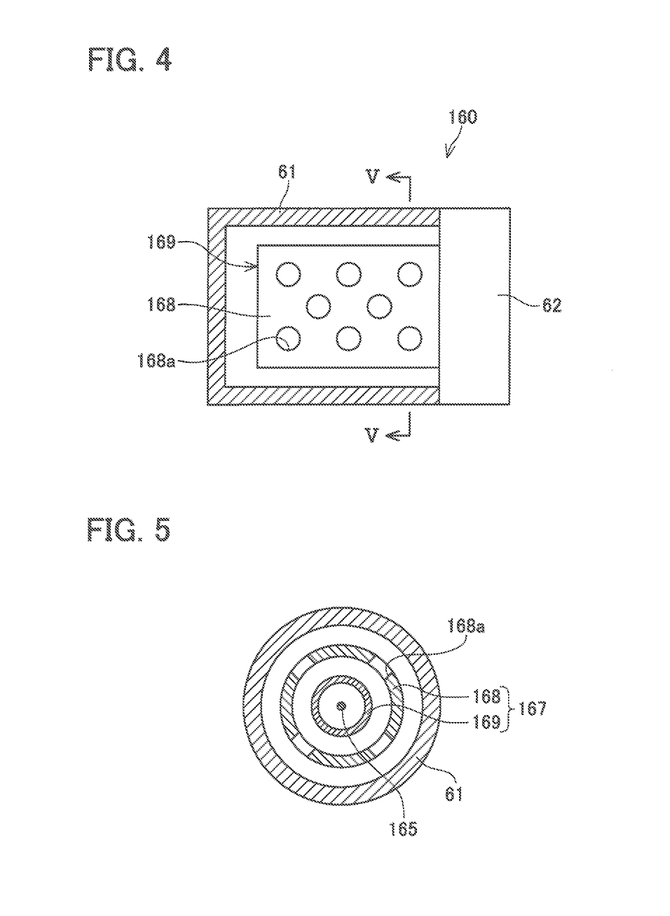

The second embodiment is described in terms of its differences from the first embodiment. As shown in FIGS. 4 and 5, the sensor device 2 of the second embodiment includes a liquid property detecting unit 160 instead of the liquid property detecting unit 60. Further, the electrode part 76 of the liquid level detecting unit 70 includes the electrode pair 81 but does not include the electrode pair 83.

The liquid property detecting unit 160 includes a case 61, a terminal part 62, a temperature detecting element 165, and an electrode pair 167. The electrode pair 167 is fixed to the terminal part 62, and is housed in the case 61. The electrode pair 167 includes electrodes 168 and 169. The electrode 168 is in the shape of a circular cylinder. The electrode 168 has formed therein a plurality of communicating holes 168a that connect an inner side of the circular cylinder and an outer side of the circular cylinder. As with the electrode 68, the electrode 168 is supplied with a signal by the control device 80. Housed inside of the electrode 168 is the electrode 169. The electrode 169 is in the shape of a circular cylinder. It should be noted that each of the electrodes 168 and 169 may be in the shape of a polygonal cylinder other than a circular cylinder. The electrode 169 is disposed concentrically with the electrode 168. The electrode 169 is grounded via the control device 80.

As in the first embodiment, this configuration makes it possible to restrain a foreign matter from making contact with the electrode pair 167. Further, since the electrode 168 has the plurality of communicating holes 168a formed therein, passage of the fuel through the space between the electrodes 168 and 169 is facilitated. This makes it possible to prevent the fuel between the electrodes 168 and 169 from being stagnant.

The temperature detecting element 165 is housed inside of the electrode 169. The temperature detecting element 165 has the same configuration as the temperature detecting element 65.

As in the first embodiment, the control device 80 detects an ethanol concentration by using the temperature of the fuel and the capacitance of the electrode pair 167. Further, as compared with the first embodiment, the control device 80 detects the liquid level of the fuel by using the capacitance of the electrode pair 167 and the capacitance of the electrode pair 81 instead of using the capacitance of the electrode pair 83.

### Third Embodiment

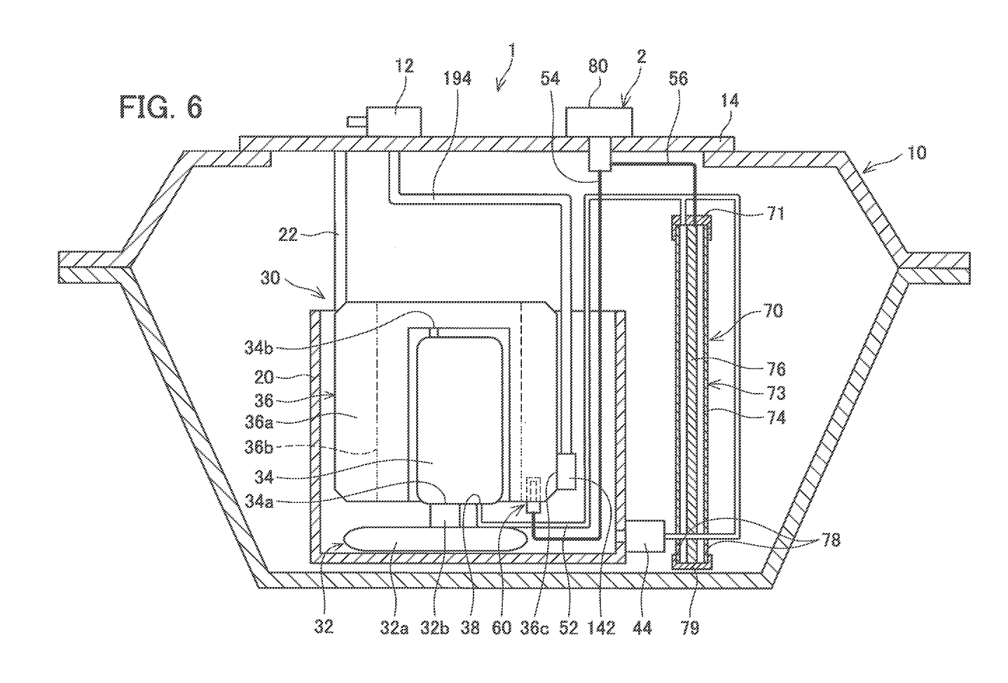

The third embodiment is described in terms of its differences from the first embodiment. As shown in FIG. 6, the sensor device 2 includes a high-pressure filter 36 in addition to the low-pressure filter 32. In a modification, the sensor device 2 may include the high-pressure filter 36 instead of the low-pressure filter 32. The liquid property detecting unit 60 is housed in the case 36a of the high-pressure filter 36. The liquid property detecting unit 60 is disposed closer to the outside than a filter member 36b of the high-pressure filter 36. The filter member 36b is made of unwoven fabric. The liquid property detecting unit 60 is disposed near a discharge opening 36c of the case 36a. Although illustrated in a simplified manner in FIG. 6, the filter member 36b is in the shape of a circular cylinder disposed concentrically with the case 36a. While the pump body 34 is driving, the fuel discharged from the pump body 34 flows through the outlet 34b, the filter member 36b, and then the discharge opening 36c into a pressure regulator 142 disposed lateral to the case 36a. It should be noted that the pressure regulator 142 is the same as the pressure regulator 42 of the first embodiment. The fuel discharged from the pressure regulator 142 passes through a pipe 194 to the discharge port 12. It should be noted that the pipe 194 is the same as the pipe 94 of the first embodiment.

According to this configuration, while the pump body 34 drives, the electrode pair 67 is located downstream of the filter member 36b in the direction of the flow of the fuel, i.e. in the direction from the outlet 34b to the discharge opening 36c. In other words, while the pump body 34 is driving, the outlet 34b, the filter member 36b, the electrode pair 67, the discharge opening 36c, and the pipe 194 are disposed in this order from the upstream side in the direction of the flow of the fuel. This in turn makes it possible, as in the first embodiment, to restrain a foreign matter from making contact with the electrode pair 67. Further, since the electrode pair 67 is disposed inside of the case 36a, space in which to dispose the electrode pair 67 does not need to be provided outside of the case 36a. Furthermore, since the electrode pair 67 is disposed upstream of the pipe 194, space in which to dispose the electrode pair 67 does not need to be provided downstream of the pipe 194.

Further, the electrode pair 67 is disposed upstream of the pipe 194. According to this configuration, a case or the like in which to dispose the electrode pair 67 does not need to be provided downstream of the pipe 194, i.e. in a fuel tithe located lateral to the fuel tank 10. This in turn makes it possible to prevent the fuel from flowing out to the outer side of the fuel tank 10 due to a failure in the part where the fuel tube and the case have been joined together or in the case per se. Further, in this configuration, the electrode pair 67 is disposed upstream as compared with the case where the electrode pair 67 is disposed downstream of the pipe 194. Ibis allows relatively early detection of a liquid, such as diesel fuel, that is not supposed to be fed to but has been fed to the fuel tank 10. The employment of a configuration in which the pump body 34 is stopped in a case where a liquid that is not supposed to be fed to the fuel tank 10 has been detected makes it possible to restrain such a liquid from being fed out of the fuel tank 10 (for example, into the engine).

Further, the filter member 36b has a function of restraining a foreign matter from making contact with the electrode pair 67 and a function of restraining the foreign matter from entering the engine. For this reason, other filter member for restraining the foreign matter from entering the engine does not need to be disposed separately from the filter member 36b.

### Modifications

(1) In each of the embodiments described above, the sensor device 2 detects the concentration of ethanol in the fuel by using the liquid property detecting unit 60. However, the sensor device 2 may detect the degree of deterioration of the fuel (for example, the degree of oxidization of the fuel). In the present modification, the degree of deterioration is an example of a “liquid property”.

(2) The “liquid property detecting device” may be used for detecting the liquid property of a liquid other than the fuel, for example cooling water (for example, the degree of deterioration of or the type of cooling water).

(3) The shape of each of the electrode pairs 67, 81, 83, and 167 is not limited to the aforementioned shape. For example, at least one electrode of each of the electrode pairs may be in the shape of a flat plate, a pillar, or a polyhedron.

(4) In each of the embodiments described above, as a result of a comparison in capacitance between the electrode pairs 67 and 83, the control device 80 outputs, to the display device of the automobile, information indicating that there is an abnormality in the sensor device 2. Alternatively, as a result of a comparison in capacitance between the electrode pairs 67 and 83, the control device 80 may output, to the display device of the automobile, information indicating the degree of difference in capacitance (i.e. information indicating that the difference is relatively great or that the difference is relatively small). Further, the control device 80 may output, to a sound output device, information obtained from the result of the comparison. The sound output device may output, in the form of a sound, the information obtained from the result of the comparison. In general, the control device 80 may output the result of the comparison in capacitance between the electrode pairs 67 and 83 or the information obtained from the result of the comparison to a device that utilizes the result or the information.

1. A liquid property detecting device configured to be disposed in a liquid feeding unit including a container, a pump configured to suck liquid stored in the container and send out the liquid toward a liquid-utilizing device, and a feed pipe arranged inside the container and communicating an outlet of the pump and a discharge opening through which the liquid is discharged out of the container,
the liquid property detecting device comprising:
a first pair of electrodes configured to be disposed upstream of the feed pipe in a direction in which the liquid stored in the container flows while the pump is driving, and configured to detect a liquid property of the liquid stored in the container; and
a filter configured to be disposed upstream of the first pair of electrodes in the direction in which the liquid stored in the container flows while the pump is driving.

2. The liquid property detecting device as in claim 1, wherein
the filter includes a housing space in which the first pair of electrodes is housed; and
the housing space is configured to communicate with a suction opening of the pump.

3. The liquid property detecting device as in claim I, further comprising:
a case housing the filter and the first pair of electrodes, wherein
the case is disposed in the container and configured to connect the outlet of the pump and the feed pipe.

4. The liquid property detecting device as in claim I, further comprising:
a substrate having a surface on which the first pair of electrodes is disposed, wherein
the surface of the substrate is configured to be disposed in an orientation that faces a bottom surface of the container.

5. The liquid property detecting device as in claim 1, wherein
the first pair of electrodes comprises:
an outer electrode having a cylindrical shape; and
an inner electrode being disposed on an inner side of the outer electrode, and facing an inner circumferential surface of the outer electrode, and
the outer electrode comprises a communicating hole that connects an outer side of the outer electrode and the inner side of the outer electrode.

6. The liquid property detecting device as in claim 1, further comprising:
a protective wall covering the first pair of electrodes, the protective wall being located closer to the first pair of electrodes than the filter member, wherein
the protective wall comprises liquid permeability.

7. The liquid property detecting device as in claim 6, wherein
the protective wall is made of a metal material, and is grounded.

8. The liquid property detecting device as in claim 1, further comprising:
a second pair of electrodes configured to be disposed in of the container and detect a liquid level of the liquid stored in the container.

9. The liquid property detecting device as in claim 8, further comprising:
a control unit configured to detect the liquid level of the liquid stored in the container by using a capacitance of the first pair of electrodes and a capacitance of the second pair of electrodes.

10. The liquid property detecting device as in claim 8, further comprising:
a third pair of electrodes configured to be disposed in the container so as to detect the liquid property of the liquid stored in the container; and
a control unit configured to detect the liquid level of the liquid stored in the container that, using a capacitance of the third pair of electrodes and a capacitance of the second pair of electrodes, wherein
the control unit is configured to output a result of a comparison between the capacitance of the first pair of electrodes and the capacitance of the third pair of electrodes.
